(19) United States
(12) Patent Application Publication
(10) Pub. No.: US 2015/0221621 A1
(43) Pub. Date: Aug. 6, 2015

(54) SEMICONDUCTOR MODULE

(71) Applicant: DENSO CORPORATION, Kariya-city (JP)

(72) Inventor: Akira MOCHIDA, Nagoya-city (JP)

(21) Appl. No.: 14/599,663

(22) Filed: Jan. 19, 2015

(30) Foreign Application Priority Data
Feb. 5, 2014 (JP) 2014-20690

(51) Int. Cl. H01L 25/10; H01L 23/495; H05K 1/02; H01L 23/31

(52) U.S. Cl. CPC H01L 25/105; H01L 23/3107; H01L 23/49517; H01L 23/49541; H01L 23/49568; H05K 1/0203

(57) ABSTRACT

A semiconductor module includes a semiconductor device and a flexible relay member. The semiconductor device includes a resin member, an electronic component sealed with the resin member, and a lead member having an inner lead and an outer lead. The inner lead is located inside the resin member and electrically connected to the electronic component. The outer lead extends from the inner lead and is located outside the resin member. The relay member is electrically connected to the outer lead to electrically connect the electronic component to a connection target to be electrically connected to the semiconductor device.

### CROSS REFERENCE TO RELATED APPLICATION

This application is based on Japanese Patent Application No. 2014-20690 filed on Feb. 5, 2014, the contents of which are incorporated herein by reference.

### FIELD

The present disclosure relates to a resin-seal type semiconductor module.

### BACKGROUND

As disclosed in JP2009-212302A corresponding to US2009/0224398A1, a resin-seal type semiconductor module is known. This type of semiconductor module includes an electronic component (i.e., a semiconductor element), a sealing resin for sealing the electronic component, a lead member electrically connected to the electronic component. The lead member includes an inner lead and an outer lead. The inner lead is located inside the sealing resin. The outer lead extends from the inner lead and is located outside the sealing resin.

In the above conventional semiconductor module, the outer lead is soldered to a connection target such as a circuit board. Further, the outer lead is connected to the connection target through a rigid relay member such as a busbar. Therefore, vibration from the connection target may be applied to the lead member, and thermal stress between the connection target and the relay member may be applied to the lead member. As a result, the sealing resin may be detached from the lead member (i.e., the inner lead).

### SUMMARY

In view of the above, it is an object of the present disclosure to provide a semiconductor module having a structure for preventing a sealing resin member from being detached from a lead member.

According to an aspect of the present disclosure, a semiconductor module includes a semiconductor device and a flexible relay member. The semiconductor device includes a resin member, an electronic component sealed with the resin member, and a lead member having an inner lead and an outer lead. The inner lead is located inside the resin member and electrically connected to the electronic component. The outer lead extends from the inner lead and is located outside the resin member. The relay member is electrically connected to the outer lead to electrically connect the electronic component to a connection target to be electrically connected to the semiconductor device.

Since the relay member has flexibility, external force applied to the lead member is absorbed by the relay member. Accordingly, the resin member can be prevented from being detached from the lead member. Examples of the external force applied to the lead member include vibration transmitted from the connection target and thermal stress between the connection target and the relay member.

For example, the relay member can be crimped to the outer lead. In such an approach, the relay member can be connected to the outer lead without using heat. Accordingly, thermal stress between the lead member and the resin member is reduced, so that the resin member can be prevented from being detached from the lead member. Further, since no additional member is required to connect the relay member to the outer lead, the number of parts in the semiconductor module can be reduced.

For example, the semiconductor device can include a heatsink configured to dissipate heat generated in the electronic component, and the lead member and the heatsink can be integral parts of a lead frame. In this case, if the whole of the lead frame is made of a material having a low thermal conductivity, the heatsink may have insufficient heat dissipation performance. On the other hand, if the whole of the lead frame is made of a material having a low tensile strength, the lead member may be broken when the relay member is crimped to the lead member.

Therefore, to ensure sufficient heat radiation performance and electrical conductivity of the heatsink while the relay member is allowed to be crimped to the lead member, the heatsink and the lead member can be made of different materials. For example, a thermal conductivity of a first material of which the heatsink is made can be higher than a thermal conductivity of a second material of which the lead member is made, and a tensile strength of the second material can be higher than a tensile strength of the first material.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a diagram illustrating a perspective view of a semiconductor module according to a first embodiment of the present disclosure;

FIG. 2 is a diagram illustrating a top view of the semiconductor module according to the first embodiment;

FIG. 3 is a diagram illustrating a side view of the semiconductor module according to the first embodiment;

FIG. 4 is a diagram illustrating a cross-sectional view taken along the line IV-IV in FIG. 2;

FIG. 5 is a diagram illustrating a method of manufacturing the semiconductor module according to the first embodiment;

FIG. 6 is a diagram illustrating the method of manufacturing the semiconductor module according to the first embodiment;

FIG. 7 is a diagram illustrating the method of manufacturing the semiconductor module according to the first embodiment;

FIG. 8 corresponds to FIG. 5 and is a diagram illustrating a method of manufacturing a semiconductor module according to a second embodiment of the present disclosure;

FIG. 9 corresponds to FIG. 2 and is a diagram illustrating a top view of a semiconductor device of a semiconductor module according to a third embodiment of the present disclosure;

FIG. 10 corresponds to FIG. 2 and is a diagram illustrating a top view of a semiconductor module according to a fourth embodiment of the present disclosure;

FIG. 11 corresponds to FIG. 3 and is a diagram illustrating a side view of a semiconductor module according to a fifth embodiment of the present disclosure;

FIG. 12 corresponds to FIG. 2 and is a diagram illustrating a top view of a semiconductor module according to a sixth embodiment of the present disclosure;

FIG. 13 is a diagram illustrating a side view of a semiconductor module according to a seventh embodiment of the present disclosure, and

FIG. 14 is a diagram illustrating a connection structure between a semiconductor device and a connector of the semiconductor module according to the seventh embodiment.

### DETAILED DESCRIPTION

Embodiments of the present disclosure are described below with reference to the drawings in which like characters of reference indicate the same or equivalent parts. Throughout the embodiments, a direction in which a semiconductor element, an electrode pad and a heatsink are stacked is defined as a Z direction, a direction which is perpendicular to the Z direction and in which a terminal extends is defined as a Y direction, and a direction perpendicular to both the Y direction and the Z direction is defined as a X direction. A XY plane defined by the X direction and the Y direction is perpendicular to the Z direction. A shape along the XY plane is referred to as the planer shape unless otherwise stated.

### First Embodiment

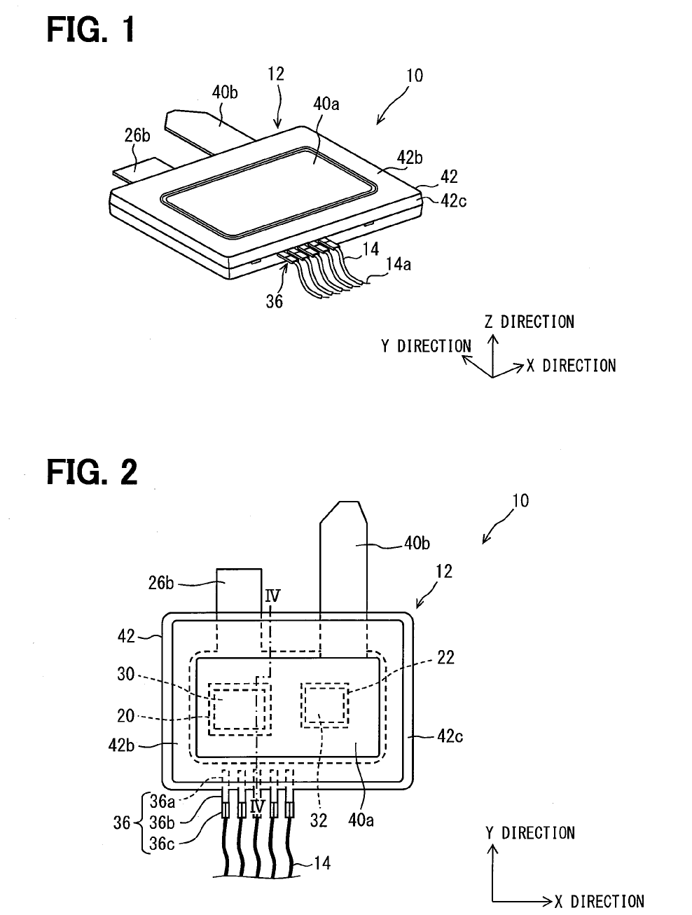

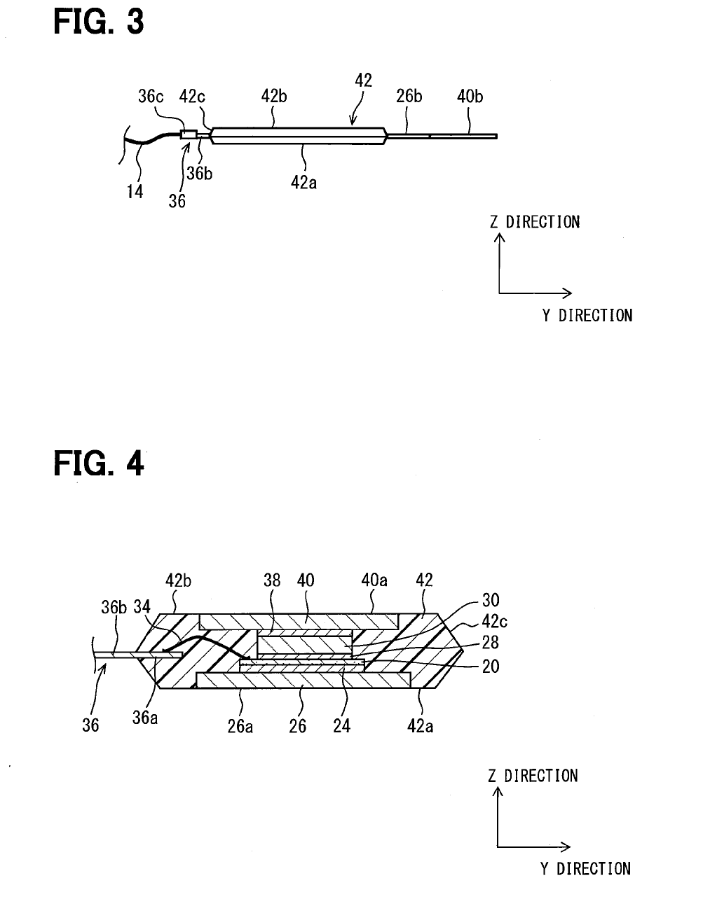

A semiconductor module 10 according to a first embodiment of the present disclosure is described below with reference to FIGS. 1-7. Firstly, an overall structure of the semiconductor module 10 is described with reference to FIGS. 1-4. As shown in FIGS. 1-3, the semiconductor module 10 includes a semiconductor device 12 and a twisted wire 14.

The semiconductor device 12 is configured as a so-called “1-in-1 package”. For example, the semiconductor device 12 is incorporated in an inverter circuit of a vehicle to perform PWM control of an electrical load.

The semiconductor device 12 has two semiconductor elements 20 and 22. The semiconductor element 20 is configured such that an insulated-gate bipolar transistor (IGBT) is formed in a semiconductor chip. For example, according to the first embodiment, the semiconductor element 20 is an N-channel IGBT. The semiconductor element 22 is configured such that a freewheeling diode (FWD) is formed in a semiconductor chip. The semiconductor element 20 corresponds to an electronic component recited in claims.

Each of the semiconductor elements 20 and 22 has a vertical structure in which an electric current flows in the Z direction and has electrodes on a first surface and a second surface opposite to the first surface in the Z direction. Specifically, the semiconductor element 20 has an emitter electrode, a gate electrode, and a control pad on the first surface facing a first surface of an electrode pad 30 and has a collector electrode on the second surface. On the other hand, the semiconductor element 22 has an anode electrode on the first surface and has a cathode electrode on the second surface. That is, the emitter electrode of the semiconductor element 20 and the anode electrode of the semiconductor element 22 are formed on the same side, and the collector electrode of the semiconductor element 20 and the cathode electrode of the semiconductor element 22 are formed on the same side.

The collector electrode of the semiconductor element 20 is electrically, thermally, and mechanically connected to a first heatsink 26 through a solder member 24. Likewise, the cathode electrode of the semiconductor element 22 is electrically, thermally, and mechanically connected to the first heatsink 26 through a solder member (not shown). The first heatsink 26 corresponds to a heatsink recited in claims.

The first heatsink 26 has a function to dissipate heat generated in the semiconductor elements 20 and 22 outside the semiconductor device 12. The first heatsink 26 is made of metal so that it can have both thermal conductivity and electrical conductivity. For example, the first heatsink 26 can be made of copper, copper alloy, or aluminum alloy, which has high thermal conductivity and high electrical conductivity. The first heatsink 26 has a first surface and a second surface opposite to the first surface of the first heatsink 26 in the Z direction. The first surface of the first heatsink 26 faces the semiconductor elements 20 and 22 and is covered with a sealing resin member 42. A side surface between the first and second surfaces of the first heatsink 26 is also converted with the sealing resin member 42. It is noted that a region of the first surface of the first heatsink 26 where a solder joint is formed is not covered with the sealing resin member 42. As shown in FIG. 4, the second surface of the first heatsink 26 is exposed outside the sealing resin member 42 and serves as a heat-dissipating surface 26a. Specifically, the sealing resin member 42 has a first surface 42a, a second surface 42b opposite to the first surface 42a in the Z direction, and a side surface 42c between the first surface 42a and the second surface 42b, and the second surface of the first heatsink 26 is exposed to the first surface 42a.

The first heatsink 26 has a terminal 26b serving as both a collector terminal of the IGBT formed in the semiconductor element 20 and a cathode terminal of the FWD formed in the semiconductor element 22. The terminal 26b extends from the side surface 42c in the Y direction and is partially exposed outside the sealing resin member 42. Thus, the terminal 26b can be electrically connected to an external device.

The emitter electrode is formed on a predetermined region of the first surface of the semiconductor element 20 and electrically, thermally, and mechanically connected to the first surface of the electrode pad 30 through a solder member 28. Likewise, the anode electrode of the semiconductor element 22 is electrically, thermally, and mechanically connected to an electrode pad 32 (refer to FIG. 2) through a solder member (not shown).

Since the electrode pad 30 is located somewhere in a thermal and electrical conduction path between a second heatsink 40 and the semiconductor element 20, the electrode pad 30 is made of metal so that it can have both thermal conductivity and electrical conductivity. Likewise, since the electrode pad 32 is located somewhere in a thermal and electrical conduction path between the second heatsink 40 and the semiconductor element 22, the electrode pad 32 is made of metal so that it can have both thermal conductivity and electrical conductivity. For example, each of the electrode pads 30 and 32 can be made of copper or molybdenum, which has high thermal conductivity and high electrical conductivity.

Further, the control pad (not shown) is formed on an outer region of the first surface of the semiconductor element 20 except the region where the emitter electrode is formed. A control terminal 36 is electrically connected to the control pad through a bonding wire 34.

The control terminal 36 extends in the Y direction. A part of the entire length of the control terminal 36 is encapsulated in (i.e., sealed with) the sealing resin member 42, and the remaining length of the control terminal 36 extends from inside to outside the sealing resin member 42. That is, the control terminal 36 has an inner lead 36a located inside the sealing resin member 42 and has an outer lead 36b extending from the inner lead 36a and located outside the sealing resin member 42. The bonding wire 34 is connected to the inner lead 36a. The control terminal 36 corresponds to a lead member recited in claims.

According to the first embodiment, the outer lead 36b has a crimp contact 36c on its tip end. A twisted wire 14 is crimped to the crimp contact 36c of the outer lead 36b so that the twisted wire 14 can be fixed to the outer lead 36b. Thus, the control terminal 36 is electrically connected to the twisted wire 14. The control terminal 36 is made of the same material as the first heatsink 26. The semiconductor device 12 has five control terminals 36: one is for Kelvin emitter, another is for the gate electrode, another is for current sensing, and the remaining two is for temperature sensing.

A second surface of the electrode pad 30 is electrically, thermally, and mechanically connected to the second heatsink 40 through a solder member 38. The first and second surfaces of the electrode pad 30 are opposite to each other in the Z direction. The electrode pad 32 is also connected to the second heatsink 40 through a solder member. Like the first heatsink 26, the second heatsink 40 has a function to dissipate the heat generated in the semiconductor elements 20 and 22 outside the semiconductor device 12.

Like the first heatsink 26, the second heatsink 40 is made of metal so that it can have both thermal conductivity and electrical conductivity. For example, the second heatsink 40 can be made of copper, copper alloy, or aluminum alloy, which has high thermal conductivity and high electrical conductivity. The second heatsink 40 has a first surface and a second surface opposite to the first surface of the second heatsink 40 in the Z direction. The first surface of the second heatsink 40 faces the electrode pads 30 and 32 and is covered with the sealing resin member 42. A side surface between the first and second surfaces of the second heatsink 40 is also converted with the sealing resin member 42. It is noted that a region of the first surface of the second heatsink 40 where a solder joint is formed is not covered with the sealing resin member 42. As shown in FIG. 4, the second surface of the second heatsink 40 is exposed outside the sealing resin member 42 and serves as a heat-dissipating surface 40a. Specifically, the second surface of the second heatsink 40 is exposed to the second surface 42b of the sealing resin member 42.

The second heatsink 40 has a terminal 40b serving as both an emitter terminal of the IGBT formed in the semiconductor element 20 and an anode terminal of the FWD formed in the semiconductor element 22. The terminal 40b extends from the side surface 42c in the Y direction and is partially exposed outside the sealing resin member 42. Thus, the terminal 26b can be electrically connected to the external device. As shown in FIGS. 1 and 2, the terminals 26b and 40b are misaligned with each other in the X direction. Further, the side surface 42c from which the terminal 40b extends is opposite in the Y direction to the side surface 42c from which the control terminal 36 extends.

Thus, the semiconductor elements 20 and 22, part of the first heatsink 26, the electrode pads 30 and 32, part of the control terminal 36, the bonding wire 34, the solder members 24, 28, and 38, and part of the second heatsink 40 are encapsulated in the sealing resin member 42. The sealing resin member 42 is formed in a rectangular shape in plan view by injecting resin into a mold. For example, the sealing resin member 42 can be made of epoxy resin.

As described above, the heat-dissipating surface 26a of the first heatsink 26 is exposed to the first surface 42a of the sealing resin member 42 in such a manner that the heat-dissipating surface 26a is substantially flush with the first surface 42a, and the heat-dissipating surface 40a of the second heatsink 40 is exposed to the second surface 42b of the sealing resin member 42 in such a manner that the heat-dissipating surface 40a is substantially flush with the second surface 42b. Further, the control terminal 36 extends from one side of the side surface 42c of the sealing resin member 42, and the terminals 26b and 40b extend from the other side of the side surface 42c in the Y direction.

The twisted wire 14 is formed by twisting multiple conductors 14a and covering the twisted conductors 14a with an electrically insulating coating. The twisted wire 14 corresponds to a relay member recited in claims. Since the twisted wire 14 is formed by twisting multiple conductors 14a, the twisted wire 14 has high bendability. Therefore, the twisted wire 14 is highly resistant to twisting and bending force applied to it. That is, the twisted wire 14 has flexibility. The conductors 14a are exposed outside the insulating coating at an end of the twisted wire 14, and the exposed portions of the conductors 14a are crimped to the crimp contact 36c of the outer lead 36b. In the description below, a connection of the twisted wire 14 to the control terminal 36 (i.e., the outer lead 36b) indicates a connection of the conductors 14a to the control terminal 36.

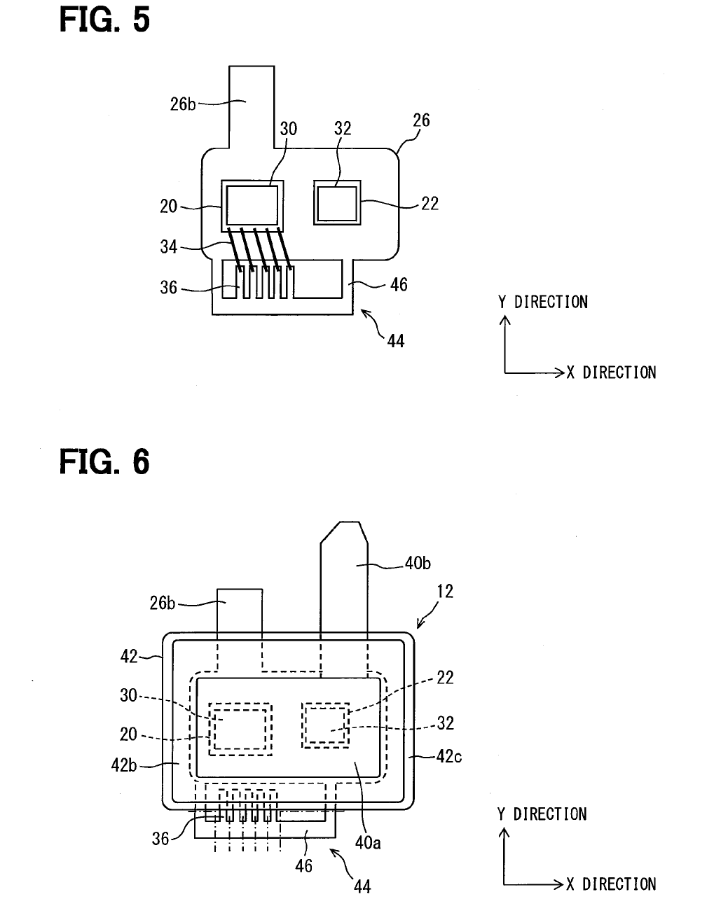

Next, a method of manufacturing the semiconductor module 10 is described below with reference to FIGS. 5-7.

Firstly, a lead frame 44 shown in FIG. 5 is prepared. The lead frame 44 is formed by stamping a copper plate into a predetermined shape and then partially bending it. The lead frame 44 has the first heatsink 26 and the control terminal 36 as its integral parts. The control terminal 36 is coupled to the first heatsink 26 by a bridge 46. As necessary, the lead frame 44 can be subjected to surface treatment such as plating for antioxidation or the like.

The semiconductor elements 20 and 22, and the electrode pads 30 and 32 are prepared in addition to the lead frame 44. According to the first embodiment, the electrode pads 30 and 32 are provided with solder members in advance. Specifically, the solder member 28 is preformed on the first surface of the electrode pad 30, and the solder member 38 is preformed on the second surface of the electrode pad 30. The same is true for the electrode pad 32.

Then, a first reflow process is performed. In the first reflow process, the semiconductor element 20 is stacked on the first heatsink 26 of the lead frame 44 through a solder member 24 (e.g., solder foil), and the electrode pad 30 on which the solder member 28 is preformed is stacked on the semiconductor element 20 in such a way that the solder member 28 can face the semiconductor element 20. Then, the solder members 24, 28, and 38 are reflowed under the condition where the first heatsink 26, the semiconductor element 20, and the electrode pad 30 are stacked in this order. Further, in the first reflow process, the semiconductor element 22 is stacked on the first heatsink 26 through a solder member (e.g., solder foil), and the electrode pad 32 on which a solder member is preformed is stacked on the semiconductor element 22. Then, the solder members in contact with the semiconductor element 22 and the electrode pad 32 are reflowed.

Since the second heatsink 40 as a connection target for the solder member 38 is not used yet in the first reflow process, the solder member 38 is shaped by surface tension like a mountain having a top at the center of the electrode pad 32. In the first reflow process, the semiconductor element 20 is soldered to the first heatsink 26, and the electrode pad 30 is soldered to the semiconductor element 20. For sake of simplicity, the solder member 38 on the electrode pad 30 and the solder member on the electrode pad 32 are omitted in FIG. 5.

Next, a wire bonding process is performed. In the wire bonding process, the control terminal 36 is connected to the semiconductor element 20 by the bonding wire 34.

Then, a second reflow process is performed. In the second reflow process, the second heatsink 40 is placed on a base (not shown), and the lead frame 44 to which the semiconductor elements 20 and 22 and the electrode pads 30 and 32 remains connected is placed on the second heatsink 40 in such a manner that the solder member 38 faces the second heatsink 40. Then, the solder member 38 is reflowed while applying pressure to the first heatsink 26 in the Z direction. As a result, the electrode pad 30 is connected to the second heatsink 40 by the solder member 38. Likewise, in the second reflow process, the electrode pad 32 is connected to the second heatsink 40.

Next, a molding process to form the sealing resin member 42 is performed. In the molding process, a structure obtained in the second reflow process is placed in a mold (not shown), and then resin is injected in a cavity of the mold so that the sealing resin member 42 can be formed. According to the first embodiment, the sealing resin member 42 is formed by transfer molding using epoxy resin. In the molding process, the sealing resin member 42 is formed so that at least one of the first and second heatsinks 26 and 40 can be entirely encapsulated in the sealing resin member 42. A reason for this is that the heat-dissipating surfaces 26a and 40a sides of the first and second heatsinks 26 and 40 are cut off in a cutting process as described later.

Next, the cutting process is performed. In the cutting process, the first heatsink 26 and the sealing resin member 42 are partially cut off from the first surface 42a side by using a cutting tool (not shown). Thus, only the heat-dissipating surface 26a out of the first heatsink 26 is exposed outside the sealing resin member 42, and the heat-dissipating surface 26a becomes substantially flush with the first surface 42a. Likewise, the second heatsink 40 and the sealing resin member 42 are partially cut off from the second surface 42b side by using the cutting tool. Thus, only the heat-dissipating surface 40a out of the second heatsink 40 is exposed outside the sealing resin member 42, and the heat-dissipating surface 40a becomes substantially flush with the second surface 42b. Since both the first heatsink 26 and the second heatsink 40 are partially cut off to form the heat-dissipating surfaces 26a and 40a, a high degree of flatness of each of the heat-dissipating surfaces 26a and 40a can be ensured while a high degree of parallelism between the heat-dissipating surfaces 26a and 40a can be ensured.

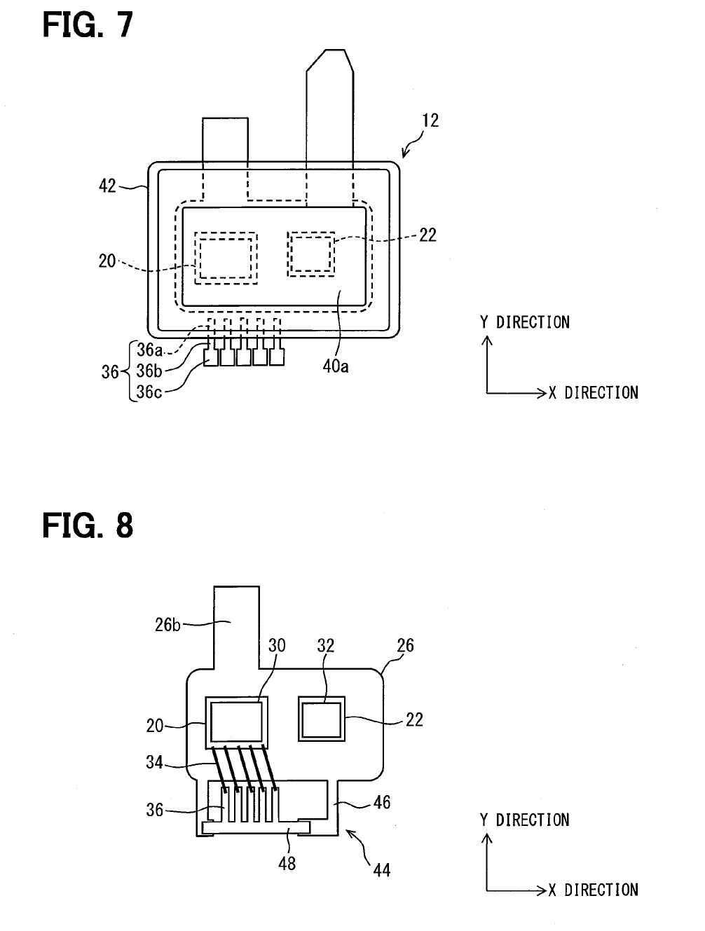

As shown in FIG. 6, after the cutting process, unnecessary portions of the lead frame 44 is removed by cutting the lead frame 44 along a dashed-dotted line in FIG. 6, so that the first heatsink 26 can be separated from the control terminal 36. That is, a portion of the bridge 46 exposed outside the sealing resin member 42 is removed. Al this time, as shown in FIG. 7, the lead frame 44 is cut so that the crimp contact 36c having a predetermined width can be formed at the end of the outer lead 36b of the control terminal 36.

After the lead frame 44 is cut, the twisted wire 14 is crimped to the crimp contact 36c. Thus, the twisted wire 14 is electrically connected to the semiconductor element 20 and, by extension, the semiconductor device 12. Alternatively, the cutting of the lead frame 44 can be performed after the molding process and before the cutting process. By performing the above processes, the semiconductor module 10 can be manufactured.

Next, effects of the semiconductor module 10 are described.

According to the first embodiment, the twisted wire 14 is connected to the outer lead 36b of the control terminal 36, and the semiconductor element 20 is electrically connected through the twisted wire 14 to a connection target such as a circuit board (not shown). The circuit board has a control circuit, such as a pulse-width modulation (PWM) signal generation circuit, for driving and controlling the IGBT formed in the semiconductor element 20. Thus, external force applied to the control terminal 36 can be absorbed by the twisted wire 14 because the twisted wire 14 has flexibility. Accordingly, the sealing resin member 42 can be prevented from being detached from the control terminal 36, and also reliability of electrical connection between the circuit board and the control terminal 36 can be improved. Examples of the external force applied to the control terminal 36 can include vibration transmitted from the control circuit and thermal stress between the circuit board and the twisted wire 14.

Further, according to the first embodiment, the twisted wire 14 is crimped to the crimp contact 36c of the outer lead 36b. Thus, the twisted wire 14 can be connected to the outer lead 36b without using heat. Accordingly, thermal stress between the control terminal 36 and the sealing resin member 42 is reduced, so that the sealing resin member 42 can be prevented from being detached from the control terminal 36. Further, since no additional member is required to connect the twisted wire 14 to the outer lead 36b, the number of parts in the semiconductor module 10 can be reduced.

### Second Embodiment

A second embodiment of the present disclosure is described below with reference to FIG. 8. The second embodiment differs from the first embodiment in the lead frame 44.

In the first embodiment, the control terminal 36 is made of the same material as the first heatsink 26. In contrast, in the second embodiment, the control terminal 36 is made of a material different from a material of which the first heatsink 26 is made. For example, the material of which the first heatsink 26 is made can have a thermal conductivity higher than that of the material of which the control terminal 36 is made. For example, the material of which the control terminal 36 is made can have a tensile strength higher than that of the material of which the first heatsink 26 is made. As necessary, the control terminal 36 can be subjected to surface treatment such as plating for antioxidation, soldering, or the like.

As shown in FIG. 8, in the lead frame 44, multiple control terminals 36 remain integrated by a coupler 48. The coupler 48 is connected to the bridge 46 which is an integral part of the first heatsink 26. For example, the connection between the coupler 48 and the bridge 46 can be achieved by soldering or crimping.

For example, according to the second embodiment, the first heatsink 26 can be made of oxygen-free copper, and the control terminal 36 can be made of brass. Oxygen-free copper has a higher thermal conductivity than brass, and brass has a higher tensile strength than oxygen-free copper. That is, although each of the first heatsink 26 and the control terminal 36 contains copper as a base material, the above relationships regarding the thermal conductivity and the tensile strength can be achieved by adding different types of metal to the base material. The base material is not limited to copper, and also the first heatsink 26 and the control terminal 36 can be made of different alloys containing different base materials.

According to the Wiedemann-Franz law, a ratio between a thermal conductivity K and an electrical conductivity p of a metal is in proportion to the absolute temperature T as follow:

K/p=LT (1)

In the equation (1), L represents what is called the Lorenz number. In theory, the Lorenz number L is give as follows:

L=π²/3×(K_{B}/e)²=2.44×10⁻⁸ WΩK⁻² (2)

In the equation (2), K_{B} represents Boltzmann coefficient, and e represents elementary charge.

From the equations (1) and (2), the ratio between the thermal conductivity and the electrical conductivity is constant regardless of types of metal, and a metal having a higher thermal conductivity has a higher electrical conductivity. Therefore, according to the second embodiment, the first heatsink 26, where a large current flows, can have both a high thermal conductivity and a high electrical conductivity.

Next, effects of the second embodiment are described.

According to the second embodiment, the twisted wire 14 having flexibility is connected to the outer lead 36b of the control terminal 36. Therefore, the same effects as obtained in the first embodiment can be obtained.

It is noted that if the whole of the lead frame 44 is made of a material having a low thermal conductivity, the first heatsink 26 may have insufficient heat dissipation performance. On the other hand, if the whole of the lead frame 44 is made of a material having a low tensile strength, the control terminal 36 may be broken when the twisted wire 14 is crimped to the crimp contact 36c of the outer lead 36b.

According to the second embodiment, although the first heatsink 26 and the control terminal 36 are integral parts of the lead frame 44, the material of which the first heatsink 26 is made has a higher thermal conductivity than the material of which the control terminal 36 is made. Further, the material of which the control terminal 36 is made has a higher tensile strength than the material of which first heatsink 26 is made. In such an approach, the twisted wire 14 can be crimped to the control terminal 36 while sufficient heat radiation performance and electrical conductivity of the first heatsink 26 are ensured.

### Third Embodiment

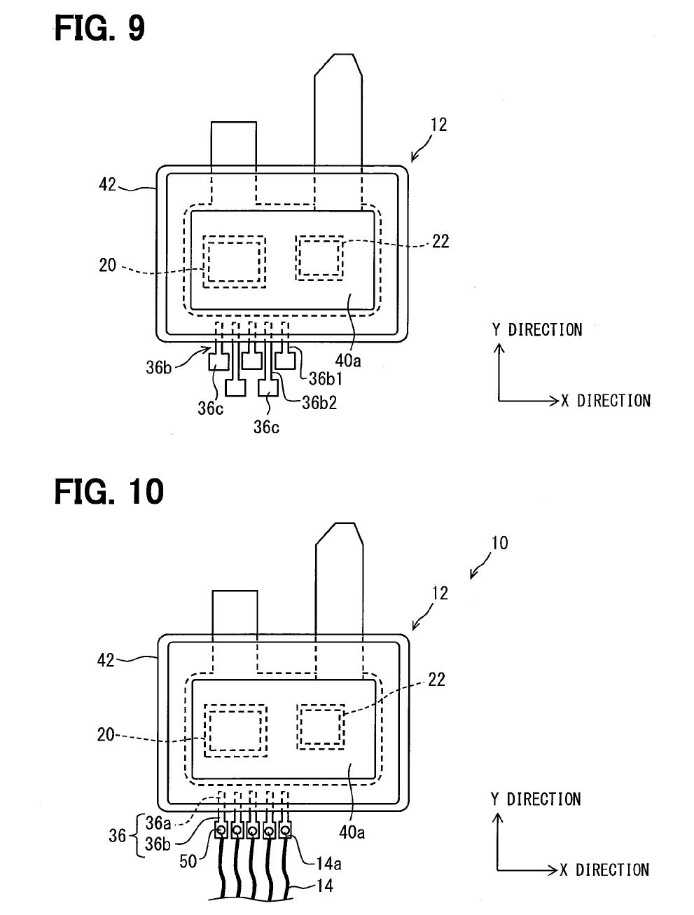

A third embodiment of the present disclosure is described below with reference to FIG. 9. The third embodiment differs from the first embodiment in the outer lead 36b.

In the third embodiment, like in the first embodiment, five control terminals 36 extend in the same direction from the side surface 42c of the sealing resin member 42. However, unlike in the first embodiment, the control terminals 36 have different lengths from the side surface 42c. In other words, the outer leads 36b exposed outside the sealing resin member 42 have different lengths. Specifically, in the third embodiment, the outer leads 36b are divided into two groups according to their lengths: first outer leads 36b1 and second outer leads 36b2. Each first outer lead 36b1 has a first length from the side surface 42c, and each second outer lead 36b2 has a second length from the side surface 42c. The second length is greater than the first length. The first outer leads 36b1 are alternated with the second outer leads 36b2 in the X direction so that the first outer lead 36b1 can be positioned in the center of the arrangement. Specifically, the first outer lead 36b1 is positioned at each end and the center of the arrangement in the X direction.

Further, the width of each crimp contact 36c in the X direction is set so that the crimp contacts 36c of adjacent outer leads 36b can overlap in the X direction. That is, the width of the crimp contact 36c is larger in the third embodiment than in the first embodiment. According to the third embodiment, the width of the crimp contact 36c of the first outer lead 36b1 is equal to the width of the crimp contact 36c of the second outer lead 36b2.

Next, effects of the third embodiment are described.

According to the third embodiment, the twisted wire 14 having flexibility is crimped to the outer lead 36b of the control terminal 36. Therefore, the same effects as obtained in the first embodiment can be obtained.

Further, according to the third embodiment, the first and second outer leads 36b1 and 36b2 having different lengths from an outer surface of the sealing resin member 42 are alternated with each other. In such an approach, the width of the crimp contact 36c can be increased without increasing the total layout area of the outer leads 36b and without increasing the width of the outer lead 36b except the crimp contact 36c. Accordingly, the twisted wire 14 can be more stably crimped to the outer lead 36b of the control terminal 36. Further, since the width of the crimp contact 36c can be increased, the thickness of the twisted wire 14 can be increased accordingly.

The arrangement of the outer leads 36b is not limited to that described in the third embodiment. For example, the second outer lead 36b2 can be positioned at each end of the arrangement. The structure described in the third embodiment can be combined with the structure described in the second embodiment.

### Fourth Embodiment

A fourth embodiment of the present disclosure is described below with reference to FIG. 10. The fourth embodiment differs from the first embodiment in how to connect the twisted wire 14 to the outer lead 36b.

In the first embodiment, the twisted wire 14 is crimped to the outer lead 36b of the control terminal 36. In contrast, in the fourth embodiment, the twisted wire 14 is connected to the outer lead 36b by a screw 50. In an example shown in FIG. 10, the conductors 14a of the twisted wire 14 are sandwiched between a head of the screw 50 and the outer lead 36b.

Next, effects of the fourth embodiment are described.

According to the fourth embodiment, the twisted wire 14 is connected to the outer lead 36b of the control terminal 36 so that the semiconductor element 20 can be electrically connected through the twisted wire 14 to the circuit board as a connection target. Therefore, like in the first embodiment, external force applied to the control terminal 36 can be absorbed by the twisted wire 14 because the twisted wire 14 has flexibility. Accordingly, the sealing resin member 42 can be prevented from being detached from the control terminal 36, and also reliability of electrical connection between the circuit board and the control terminal 36 can be improved.

Further, according to the first embodiment, the twisted wire 14 is electrically connected to the outer lead 36b by the screw 50. Thus, like in the first embodiment, the twisted wire 14 can be connected to the outer lead 36b without using heat. Accordingly, thermal stress between the control terminal 36 and the sealing resin member 42 is reduced, so that the sealing resin member 42 can be prevented from being detached from the control terminal 36.

The structure described in the fourth embodiment can be combined with the structure described in the third embodiment. That is, when a screw portion of the outer lead 36b to which the screw 50 is screwed needs to have a large width, the width of the screw portion can be increased by arranging the first outer lead 36b1 and the second outer lead 36b2 alternatively as described in the third embodiment.

### Fifth Embodiment

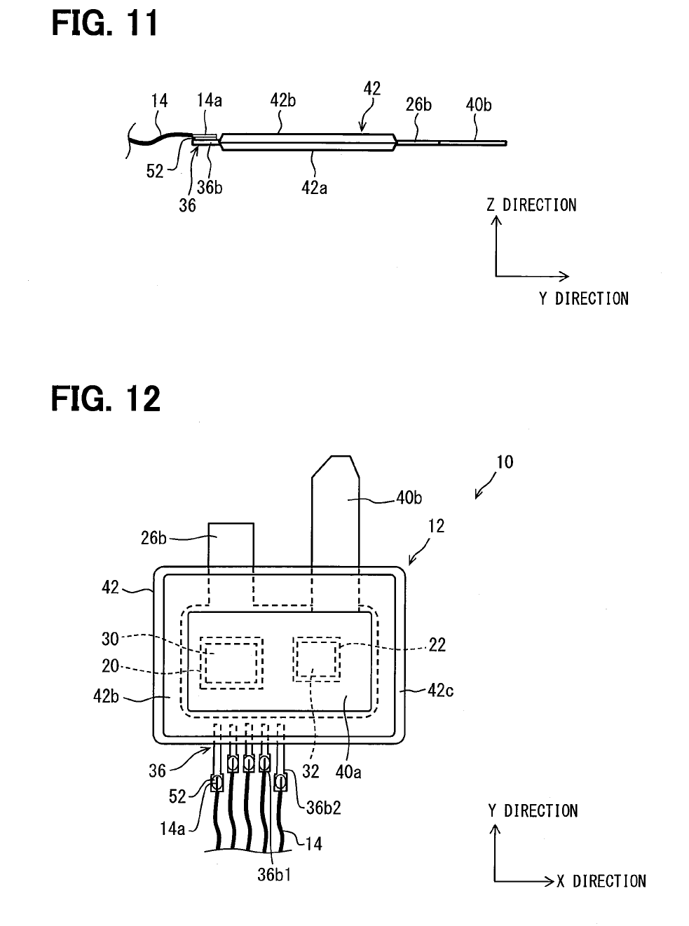

A fifth embodiment of the present disclosure is described below with reference to FIG. 11. The fifth embodiment differs from the first embodiment in how to connect the twisted wire 14 to the outer lead 36b.

In the first embodiment, the twisted wire 14 is crimped to the outer lead 36b of the control terminal 36. In contrast, in the fifth embodiment, the twisted wire 14 is connected to the outer lead 36b by a solder member 52. In an example shown in FIG. 11, the conductors 14a of the twisted wire 14 are connected through the solder member 52 to the outer lead 36b.

Next, effects of the fifth embodiment are described.

According to the fifth embodiment, the twisted wire 14 is connected to the outer lead 36b of the control terminal 36 so that the semiconductor element 20 can be electrically connected through the twisted wire 14 to the circuit board as a connection target. Therefore, like in the first embodiment, external force applied to the control terminal 36 can be absorbed by the twisted wire 14 because the twisted wire 14 has flexibility. Accordingly, the sealing resin member 42 can be prevented from being detached from the control terminal 36, and also reliability of electrical connection between the circuit board and the control terminal 36 can be improved.

Further, since the twisted wire 14 is soldered to the outer lead 36b by the solder member 52, reliability of electrical connection between the twisted wire 14 and the outer lead 36b can be improved.

The structure described in the fifth embodiment can be combined with the structure described in the fourth embodiment. That is, the first heatsink 26 and the control terminal 36, which are integral parts of the lead frame 44, can be made of different materials. In this case, it is preferable that the material of which the control terminal 36 is made should have a lower thermal conductivity and a higher tensile strength than the material of which the first heatsink 26 is made. For example, like in the second embodiment, the first heatsink 26 can be made of oxygen-free copper, and the control terminal 36 can be made of brass. In such an approach, the heat radiation performance and electrical conductivity of the first heatsink 26 are ensured, and heat generated when the twisted wire 14 is soldered to the outer lead 36b is less likely to be transferred from the control terminal 36 to the sealing resin member 42. Thus, the sealing resin member 42 is less likely to be detached.

### Sixth Embodiment

A sixth embodiment of the present disclosure is described below with reference to FIG. 12. The sixth embodiment differs from the fifth embodiment in the following aspects.

In the sixth embodiment, five control terminals 36 extend in the same direction from the side surface 42c of the sealing resin member 42. Further, like in the fifth embodiment, the twisted wire 14 is soldered to the outer lead 36b. However, unlike in the fifth embodiment, the control terminals 36 have different lengths from the side surface 42c. That is, like in the third embodiment, the outer leads 36b are divided into a first outer leads 36b1 and a second outer leads 36b2 according to their length. Each first outer lead 36b1 has a first length from the side surface 42c, and each second outer lead 36b2 has a second length from the side surface 42c. The second length is greater than the first length.

In an example shown in FIG. 12, the first outer leads 36b1 and the second outer leads 36b2 are arranged in the X direction so that the second outer lead 36b2 can be positioned at each end of the arrangement and so that the remaining three first outer leads 36b1 can be located between the second outer leads 36b2.

Next, effects of the sixth embodiment are described.

According to the sixth embodiment, the twisted wire 14 having flexibility is connected to the outer lead 36b of the control terminal 36 by the solder member 52. Therefore, the same effects as obtained in the fifth embodiment can be obtained.

Further, according to the sixth embodiment, some of the outer leads 36b are configured as the first outer lead 36b1, and the remainder of the outer leads 36b is configured as the second outer lead 36b2. In such an approach, solder joints of the outer leads 36b are misaligned in the X direction compared to when the solder joints are aligned in in the X direction, i.e., compared to when each of the outer leads 36b has the same length. Accordingly, thermal mass when the solders 52 are reflowed is distributed, and the detachment of the resin sealing member 42 due to heat becomes less likely to occur. Thus, the resin sealing member 42 can be prevented from being detached.

According to the sixth embodiment, the first outer leads 36b1 and the second outer leads 36b2 are arranged as shown in FIG. 12. The arrangement of the first outer leads 36b1 and the second outer leads 36b2 is not limited to the example shown in FIG. 12. For example, like in the third embodiment, the first outer leads 36b1 can be alternated with the second outer leads 36b2 in the X direction. Further, the first outer leads 36b1 and the second outer leads 36b2 can be arranged so that the first outer lead 36b1 can be positioned at each end of the arrangement in the X direction. Furthermore, the structure described in the sixth embodiment can be combined with the structure described in the second embodiment. That is, the first heatsink 26 and the control terminal 36, which are integral parts of the lead frame 44, can be made of different materials. In this case, it is preferable that the material of which the control terminal 36 is made should have a lower thermal conductivity and a higher tensile strength than the material of which the first heatsink 26 is made.

### Seventh Embodiment

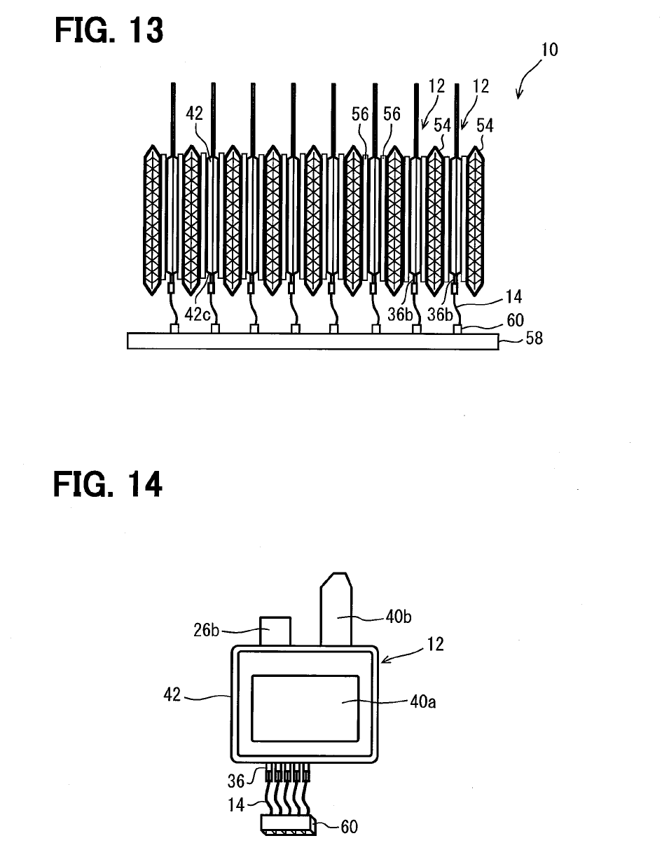

A seventh embodiment of the present disclosure is described below with reference to FIGS. 13 and 14. The seventh embodiment differs from the first embodiment in the following aspects.

As shown in FIG. 13, according to the seventh embodiment, the semiconductor module 12 has a cooler 54 in addition to the semiconductor device 20 and the twisted wire 14. The cooler 54 is configured to cool the semiconductor module 12. Specifically, the semiconductor module 12 has multiple semiconductor devices 12 and multiple coolers 54, and the semiconductor devices 12 are alternated with the cooler 52 in layers.

The outer lead 36b of each semiconductor device 12 extends from the side surface 42c of the sealing resin member 42 in the same direction. The side surface 42c connects the first surface 42a facing one cooler 54 and the second surface 42b facing another cooler 54. Each outer lead 36b is electrically connected through the twisted wire 14 to a circuit board 58 as a connection target. The circuit board 58 is shared among all the semiconductor devices 12.

As shown in FIGS. 13 and 14, each twisted wire 14 is connected to the corresponding outer lead 36b at one end and connected to an individual connector 60 at the other end. Thus, the twisted wire 14 is connected to the circuit board 58 through the connector 60.

Next, effects of the seventh embodiment are described.

In a structure for cooling semiconductor devices by alternating the semiconductor devices with coolers in layers, variations in thickness of the semiconductor devices are accumulated and may affect connection of the semiconductor devices to a circuit board. If a relay member for connecting the semiconductor device to the circuit board is rigid, and misalignment occurs between the semiconductor device and a connection portion of the circuit board, a sealing resin member may be detached by stress occurring when connecting the semiconductor devices to the circuit board.

In contrast, according to the seventh embodiment, the twisted wire 14 as a relay member for connecting the semiconductor device 12 to the circuit board 58 has flexibility. Thus, even when the semiconductor devices 12 are alternated with the coolers 54 in layers, the stress occurring when connecting the semiconductor devices 12 to the circuit board 58 is reduced. Accordingly, the detachment of the sealing resin member 42 can be prevented effectively.

According to the seventh embodiment, the twisted wire 14 is connected to the circuit board 58 through the connector 60. For example, the connector 60 can be mounted on the circuit board 58 in advance, and then the twisted wire 14 can be connected to the connector 60. Alternatively, the connector 60 can be connected to the twisted wire 14 in advance, and then the connector 60 can be mounted on the circuit board 58. Further alternatively, the connector 60 connected to the twisted wire 14 can be mated with another connector mounted on the circuit board 58.

(Modifications)

While the present disclosure has been described with reference to the embodiments, it is to be understood that the disclosure is not limited to the embodiments. The present disclosure is intended to cover various modifications and equivalent arrangements inside the spirit and scope of the present disclosure. For example, the embodiments can be modified as follows.

The number of the control terminals 36 is not limited to five and can be any number.

The structure of the semiconductor device 12 is not limited to that described in the embodiments. For example, instead of the “1-in-1 package”, the semiconductor device 12 can be configured as a “2-in-1 package” having one set of upper and lower arms for an inverter or can be configured as a “6-in-1 package” having three sets of upper and lower arms for a three-phase inverter. The present disclosure can be applied to a semiconductor module including an electronic component, a sealing resin member for sealing the electronic component, and a lead member electrically connected to the electronic component and exposed out side the sealing resin member.

The relay member is not limited to the twisted wire 14 as long as it has flexibility.

The lead member is not limited to the control terminal 36.

Such changes and modifications are to be understood as being inside the scope of the present disclosure as defined by the appended claims.

What is claimed is:

1. A semiconductor module comprising:
a resin-seal type semiconductor device including a resin member, an electronic component sealed with the resin member, and a lead member having an inner lead and an outer lead, the inner lead located inside the resin member and electrically connected to the electronic component, the outer lead extending from the inner lead and located outside the resin member, and
a flexible relay member electrically connected to the outer lead to electrically connect the electronic component to a connection target to be electrically connected to the semiconductor device.

2. The semiconductor module according to claim 1, wherein
the relay member is crimped to the outer lead.

3. The semiconductor module according to claim 2, wherein
the semiconductor device includes a heatsink configured to dissipate heat generated in the electronic component,
the lead member and the heatsink are integral parts of a lead frame,
the heatsink is made of a first material,
the lead member is made of a second material,
a thermal conductivity of the first material is higher than a thermal conductivity of the second material, and
a tensile strength of the second material is higher than a tensile strength of the first material.

4. The semiconductor module according to claim 2, wherein
the lead member has a plurality of outer leads including the outer lead,
the plurality of outer leads includes first outer leads and second outer leads,
each of the first outer leads and the second outer leads extends from a predetermined surface of the resin member in a predetermined direction,
each of the first outer leads has a first length from the surface of the resin member
each of the second outer leads has a second length from the surface of the resin member,
the second length is greater than the first length, and
the first outer leads are alternated with the second outer leads.

5. The semiconductor module according to claim 1, wherein
the relay member is connected to the outer lead by a screw.

6. The semiconductor module according to claim 1, wherein
the relay member is soldered to the outer lead.

7. The semiconductor module according to claim 6, wherein
the lead member has a plurality of outer leads including the outer lead,
the plurality of outer leads includes first outer leads and second outer leads,
each of the first outer leads and the second outer leads extends from a predetermined surface of the resin member in a predetermined direction,
each of the first outer leads has a first length from the surface of the resin member,
each of the second outer leads has a second length from the surface of the resin member, and
the second length is greater than the first length.

8. The semiconductor module according to claim 7, wherein
the semiconductor device includes a heatsink configured to dissipate heat generated in the electronic component,
the lead member and the heatsink are integral parts of a lead frame,
the heatsink is made of a first material,
the lead member is made of a second material,
a thermal conductivity of the first material is higher than a thermal conductivity of the second material, and
a tensile strength of the second material is higher than a tensile strength of the first material.

9. The semiconductor module according to claim 1, wherein
the connection target is a circuit board having a control circuit configured to drive and control the electronic component.

10. The semiconductor module according to claim 9, further comprising:
a plurality of semiconductor devices including the semiconductor device, and
a plurality of coolers configured to cool the plurality of semiconductor devices, wherein
the plurality of semiconductor devices is alternated with the plurality of coolers,
the circuit board as the connection target is shared among all the plurality of semiconductor devices,
the outer lead of each of the plurality of semiconductor devices extends from a side surface of the resin member in a predetermined direction,
the side surface connects first and second surfaces of the resin member, the first surface of the resin member faces a first one of the plurality of coolers, and
the second surface of the resin member faces a second one of the plurality of coolers.
